(19) United States
(12) Patent Application Publication
(10) Pub. No.: US 2013/0330501 A1
(43) Pub. Date: Dec. 12, 2013

(54) HIERARCHICAL STRUCTURED SURFACES TO CONTROL WETTING CHARACTERISTICS

(71) Applicants: Joanna Aizenberg, Boston, MA (US); Philseok Kim, Arlington, MA (US)

(72) Inventors: Joanna Aizenberg, Boston, MA (US); Philseok Kim, Arlington, MA (US)

(21) Appl. No.: 13/810,882

(22) PCT Filed: Jul. 19, 2011
(86) PCT No.: PCT/US11/44553

§ 371 Date: Aug. 20, 2013

Related U.S. Application Data
(60) Provisional application No. 61/365,615, filed on Jul. 19, 2010.

(51) Int. Cl. B08B 17/06; B81C 1/00

(52) U.S. Cl. CPC B08B 17/065; B81C 1/00349
USPC 428/85; 427/258; 427/140; 428/141; 428/143; 428/116

(57) ABSTRACT

A hierarchical surface having improved control of the wetting characteristics and methods for forming the same is described. The hierarchical surface includes a primary structure having at least one primary characteristic features; a secondary structure having at least one secondary characteristic features, wherein the size of the at least one secondary characteristic features are larger than the size of the at least one primary characteristic features. Moreover, the primary structure and the secondary structure synergistically provide improved mechanical properties and control of the wetting characteristics over that of the primary structure or the secondary structure alone.

### CROSS-REFERENCE TO RELATED APPLICATIONS

This application claims the benefit of the earlier filing date of U.S. Patent Application No. 61/365,615, filed on Jul. 19, 2010, the contents of which is incorporated by reference herein in its entirety.

### BACKGROUND

Structures that are resistant to wetting by liquids have been studied intensively. One proposed structures are to create high surface area, structured surfaces. However, methods for producing high surface area, structured surface coatings typically rely on extremely complex, expensive, multistep, serial and low throughput nanofabrication methods.

### SUMMARY

The present disclosure is directed to hierarchically structured surfaces to control their wetting characteristics. In certain embodiments, an article that includes a substrate having a primary structure and a secondary structure is described. In certain embodiments, the secondary structure is disposed on the substrate and the primary structure is disposed on at least a portion of the secondary structure. In certain embodiments, the primary structure has at least one primary characteristic feature having a dimension on the nanoscale and the secondary structure has at least one secondary characteristic feature having a dimension larger than the dimension of the primary characteristic features. In certain embodiments, the primary structure and the secondary structure provide improved control of wetting characteristics over that of the primary structure or the secondary structure alone.

In certain embodiments, a method for producing a hierarchical structured surface is described. In certain embodiments, the method includes providing a substrate; providing a primary structure having at least one primary characteristic features having a dimension on the nanoscale; and providing a secondary structure having at least one secondary characteristic features having a dimension larger than the dimension of the primary characteristic features. In certain embodiments, the secondary structure is disposed on the substrate and the primary structure is disposed on at least a portion of the secondary structure. In certain embodiments, the primary structure and the secondary structure provide improved control of the wetting characteristics over that of the primary structure or the secondary structure alone.

In certain embodiments, the primary structure comprises a plurality of bumps and the secondary structure comprises a plurality of protrusions extending from the surface of the bumps.

In certain embodiments, an article that includes a substrate having a primary structure, a secondary structure and a tertiary structure is described. In certain embodiments, the tertiary structure is disposed on the substrate, the secondary structure is disposed on at least a portion of the tertiary structure, and the primary structure is disposed on at least a portion of the secondary structure. In certain embodiments, the primary structure has at least one primary characteristic feature having a dimension on the nanoscale, the secondary structure has at least one secondary characteristic feature having a dimension larger than the dimension of the primary characteristic features, and the tertiary structure has at least one tertiary characteristic feature having a dimension larger than the dimension of the secondary characteristic features. In certain embodiments, the primary structure, the secondary structure, and the tertiary structure provide improved control of wetting characteristics over that of the primary structure, the secondary structure, or the tertiary structure alone.

In certain embodiments, a method for producing a hierarchical structured surface is described. In certain embodiments, the method includes providing a substrate; providing a primary structure having at least one primary characteristic features having a dimension on the nanoscale; providing a secondary structure having at least one secondary characteristic features having a dimension larger than the dimension of the primary characteristic features; and providing a tertiary structure having at least one tertiary characteristic features having a dimension larger than the dimension of the secondary characteristic features. In certain embodiments, the tertiary structure is disposed on the substrate, the secondary structure is disposed on at least a portion of the tertiary structure, and the primary structure is disposed on at least a portion of the secondary structure. In certain embodiments, the primary structure, the secondary structure, and the tertiary structure provide improved control of wetting characteristics over that of the primary structure, the secondary structure, or the tertiary structure alone.

In certain embodiments, the primary structure is disposed on at least a portion of the substrate.

In certain embodiments, the size of the at least one primary characteristic features are tens of nanometers.

In certain embodiments, the primary structure comprises a plurality of nanofibers, rods, nanoparticles, nanoballs, protrusions, or combinations thereof.

In certain embodiments, the secondary structures or tertiary structures include a plurality of posts, honeycombs, bricks, bumps and combinations thereof.

In certain embodiments, the secondary structures or the tertiary structures include a plurality of raised structures wherein the base of the raised structures have a larger dimension than the top of the raised structures.

In certain embodiments, the liquid is water, alcohol, oil, or mixtures thereof.

In certain embodiments, at least one of the primary structure or the secondary structure is repairable after damage.

In certain embodiments, the substrate is substantially non-planar.

In certain embodiments, the primary structure comprises a conducting polymer.

In certain embodiments, the hierarchical structure forms a cilia-like structure that actuates upon application of voltage in an electrolyte solution.

In certain embodiments, the hierarchical structure forms a coating for displays, electrodes, optical materials, turbines, anti-bacterial surfaces, or separation membranes.

In certain embodiments, a method of repelling a substance is described. The method includes providing an article having a hierarchical structure described herein and exposing the article to the substance.

In certain embodiments, the substance is a liquid.

In certain embodiments, the liquid is aqueous.

In certain embodiments, the liquid is organic.

In certain embodiments, the substance is a solid.

In certain embodiments, the solid is ice, frost or snow.

### BRIEF DESCRIPTION OF THE FIGURES

FIGS. 1A and 1B shows a schematic illustrations of two exemplary hierarchical structures in accordance with certain embodiments;

FIG. 2 shows a schematic illustration of methodology to modify one or more structures of the hierarchical structure in accordance with certain embodiments;

FIGS. 3A to 3E show the different morphologies that can arise by changing the electrodeposition parameters in accordance with certain embodiments;

FIGS. 4A to 4D show a schematic illustration of reparability of the hierarchical structure after damage in accordance with certain embodiments;

FIG. 5 illustrates some exemplary surfaces over which the hierarchical structures can be formed in accordance with certain embodiments;

FIGS. 6A to 6D show a series of SEM images of (a) short nanofibers on nanopost array, (b) long and entangled nanofibers on nanopost array, (c) large globular morphology decorated on nanopost array, and (d) small nanoparticles deposited on nanopost array in accordance with certain embodiments;

FIGS. 7A and 7B show SEM images of bent nanopost array decorated with polymer nanofibers and nanoballs in accordance with certain embodiments;

FIGS. 8A through 8D show SEM images of (a) nanofibers on nanoposts, (b) nanofibers on the tip of nanoposts, (c) setae-like surface and (d) nanofibers on porous inverse opal structure in accordance with certain embodiments;

FIG. 9 showing SEM images of a hierarchical structure having primary, secondary and tertiary structures in accordance with certain embodiments;

FIG. 10 shows the contact angle as a function of ethanol/deionized water ratio for the different hierarchical and non-hierarchical structures in accordance with certain embodiments;

FIG. 11 shows the contact angle on the various different hierarchical and non-hierarchical structures for different solvents in accordance with certain embodiments;

FIG. 12 shows a series of still images taken from a movie taken by a high speed camera showing a water droplet impacting different types of hierarchical and non-hierarchical structures in accordance with certain embodiments;

FIGS. 13A to 13D show a series of SEM images demonstrating the reparability of the hierarchical structure after damage in accordance with certain embodiments;

FIGS. 14A and 14B show a series of SEM images demonstrating modifying the basal portion of nanoposts to improve the mechanical stability in accordance with certain embodiments;

FIGS. 15A through 15C show a series of SEM images showing mechanical reinforcement of a secondary structure by shape transformation in accordance with certain embodiments;

FIGS. 15D and 15E show finite element modeling of the secondary structure under compressive load before and after reinforcement in accordance with certain embodiments;

FIG. 16A through 16D show a series of SEM images demonstrating formation of hierarchical structures on an Al alloy in accordance with certain embodiments; and

FIG. 17 show formation of frost on the hierarchical structures electrochemically deposited on the Al surfaces as compared to uncoated Al surfaces with and without surface modification with a fluorinated material in accordance with certain embodiments.

### DETAILED DESCRIPTION

The present disclosure relates to surfaces that are capable of controlling the wetting behavior by liquids. More particularly, the present disclosure relates to multi-hierarchical structured surfaces that are capable of controlling the wetting behavior by a broad range and classes of liquids, ranging from exemplary liquids such as water, alcohol, oil, and various other low surface tension liquids. Wetting behavior can include (but are not limited to) hydrophobicity, hydrophilicity, oleophobicity, and oleophilicity, including superhydrophobicity, superhydrophilicity, superoleophobicity, superoleophilicity, and the like. As used herein, superhydrophobicity refers to a property of a surface that does not wet by water typically with a high contact angle (>150 degree) and a low sliding angle (<10 degree) for a water droplet. As used herein, superhydrophilicity refers to a property of a surface that is wet by water typically with a very low contact angle (near zero) for a water droplet. As used herein, superoleophobicity refers to a property of a surface that does not wet by oil or hydrocarbons typically with a high contact angle (>150 degree) and a low sliding angle (<10 degree) for an oil droplet. As used herein, superoleophilicity refers to a property of a surface that is wet by oil or hydrocarbon typically with a very low contact angle (near zero) for a droplet of oil or hydrocarbon.

Varying levels of multi-hierarchical structured surfaces are within the scope of the invention. As more fully described below, the present disclosure provides surfaces with certain structures that have one or more structural features that provide improved control of the wetting characteristics. One or more different types of structures can exist, each of the particular types of structures being characterized by certain feature sizes. Features sizes, as used herein, are meant to include the dimensions of certain characteristic attributes of the structures, such as average or periodic interstructure distances, diameters of the individual nanoscale features, length of the individual nanoscale features, and the like.

In certain embodiments, the hierarchical structures of the present disclosure can provide improved wetting resistance of liquids. For example, the hierarchical structures can provide improved superhydrophobicity than compared to other conventional superhydrophobic surfaces.

In certain embodiments, the hierarchical structures of the present disclosure can provide improved tendency to wet liquids. For example, the hierarchical structures can provide improved superhydrophilicity than compared to other conventional superhydrophilic surfaces.

### Hierarchical Structures

In certain embodiments, a surface, such as a surface on a flat substrate, can be provided with structures that have a first characteristic size scale, which will be referenced as “primary structures” herein, that impart control of wetting characteristics. The features are referred to as “primary structures” as they are meant to denote the smallest feature sizes of the hierarchical structure. The primary structures can include structures, such as nanofibers, nanodots, and the like. Such nanoscale “primary structures” can have at least one feature size that is a few to tens or hundreds of nanometers in size, such as less than 5 nm to 200 nm. For example, nanofibers having diameters of approximate 5, 10, 25, 50, or even 100 nm are contemplated.

The primary structures are disposed on secondary structures that provide further improved control of wetting characteristics to the surface. The “secondary structures” are larger than the “primary structures” described above. For example, when “primary structures” having feature sizes of about 100 nm diameter are utilized, the “secondary structures” can have feature sizes that are larger than 100 nm, such as 150 nm, 300 nm, 500 nm, or 1000 nm, and larger, which in combination with the primary structures can provide characteristics, such as non-wettability, superhydrophilicity, repairability, and the like.

Additional higher order structures, such as “tertiary structures” and the like, which each have larger feature sizes than the lower order (primary and secondary) structures can optionally be included. Such additional structures can offer further benefits in addition to those imparted by the lower-order structures.

Generally, the highest order structure adhere to the substrate or the article over which the hierarchical structures are formed. In certain instances, the highest order structure can form an integral part of the underlying substrate or the article. Moreover, the lower order structure can also adhere, be integral to, or be formed over any of the lower order structures. For example, for a hierarchical having a primary, secondary and tertiary structure, the tertiary structure may be bound with strong mechanical adhesion to the underlying substrate. Moreover, the secondary material can extend from the tertiary structure and be adhered to or integrally grow from the tertiary structure. In certain embodiments, the secondary material can extend from the underlying substrate. The primary structure can similarly emanate from the secondary structure, tertiary structure, and/or the underlying substrate.

Without wishing to be bound by theory, each of the “primary, secondary, tertiary, or higher-order structures” can provide large surface area and many reentrant curvatures that are highly desirable for achieving non-wetting characteristics, even when the liquids are dynamically impacted onto the surface. As used herein, “dynamic impact” of the liquids is meant to denote liquids that are provided onto the surface with some movement or force, such as dropping/injection/impaction of the liquid onto the surface or flow along the surface or the surface that is dynamically impacting with such liquids. The use of surface features having two, three or more different dimensions provides a degree of complexity to the surface that promotes improved control of the wetting characteristics while simultaneously providing strength and robustness. Such hierarchy of structures can provide a redundant fail-safe mechanism to maintaining the desired wetting characteristics as well as the desired large surface area at many different length scales.

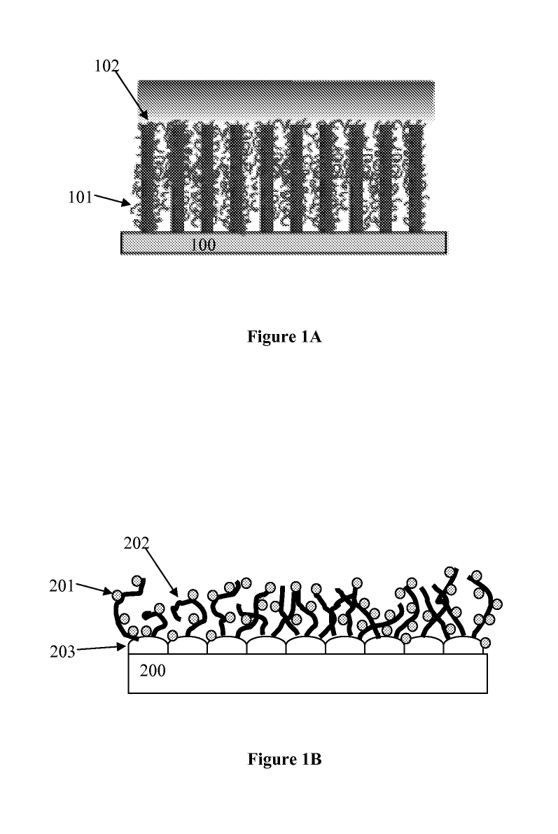

For illustrative purposes, shown in FIG. 1A, is a schematic showing “primary and secondary structures.” The rod-like cylindrical structures 102 that are standing perpendicular to the flat substrate 100 are the “secondary structures” and the hair-like structures 101 on the cylinders 102 are the “primary structures.” In this exemplary embodiment, cylinder 102 can be integral with the substrate 100, for example, having been cast from the same mold or etched from a single base. Also by way of example, the primary structure 101 can be deposited or grown on the substrate 100 and/or cylinders 102 and can have a different material composition. Additional hierarchical structures, such as “tertiary structures” (not shown), can be included and would have feature sizes that are larger than the “secondary structures” (e.g., the rod-like cylindrical structures 102). By this convention, if additional hierarchical structure having feature sizes smaller than the “primary structures” shown in the schematic are included, then this smaller sized structure will be the “primary structures” and the previously primary and secondary structures would become secondary and tertiary structures, respectively.

As one of ordinary skill in the art would appreciate, the various structures described herein, such as the “primary structures,” the “secondary structures” and the “tertiary structures” can be selected as necessary for the particular application envisioned and need not be limited to only those structure noted explicitly herein. For example, the “primary structure” need not be nanofibers, but can be array of nanoscale posts, nanoparticles or other raised structures. In another example, the “secondary structures” need not be limited to an array of posts, but can include any other raised structures, such as randomly arranged posts, cones or the like or an array of closed cell structures, array of honeycombs, array of egg closed walls, array of bricks, and the like. FIG. 1B shows an exemplary hierarchical structure having a roughened surface characterized by peaks and valleys (shown here as a plurality of bumps 203) as the tertiary structure, a plurality of nanofibers 202 as secondary structures, and a plurality of protrusions or extensions (shown here as balls 201) that are smaller than the nanofibers as the primary structures on substrate 200.

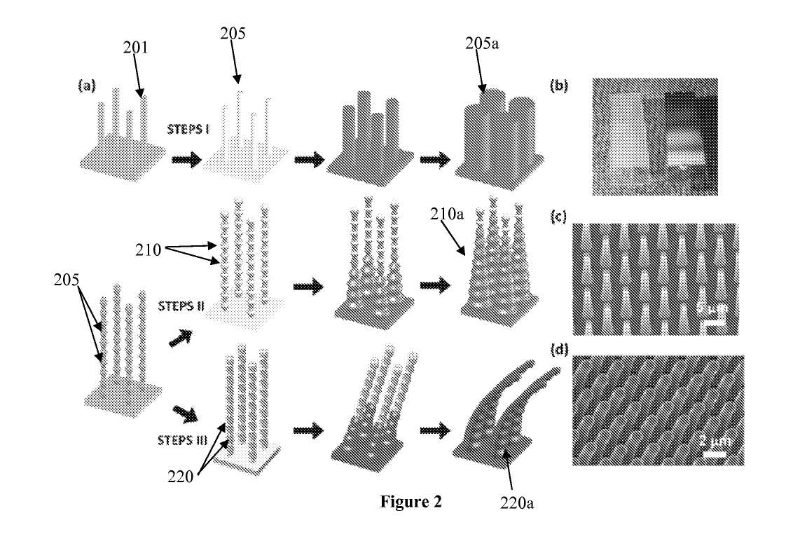

In certain embodiments, the hierarchical structures can be optimized not only to provide improved control of the wetting characteristics, but also other desirable properties, such as stability, mechanical strength, hydrophobicity, environmental stability, desired electrical and/or optical properties, and the like. For example, the array of posts, which can serve as either “primary structure” or the “secondary structure,” may be modified as shown in FIG. 2 to produce an array of thicker posts or an array of conical posts, which can improve scratch or impact resistance.

Referring to FIG. 2A, a continuous electrode (e.g., a metallized coating over nanoposts 205) can be formed on the parent substrate 206 by sputtering. Thereafter, a conductive polymer such as polypyrrole can be deposited (e.g., electrodeposition) to form a composite structure 205a of increased dimension and mechanical strength. FIG. 2B shows photographs before and after deposition of the polypyrrole.

In an alternative approach, a set of discontinuous electrodes 210 can be formed by evaporation on a metal electrode on the scalloped edges 211 of the starting raised structures 212, where the patterns reflect shadowing due to scalloping of the sidewalls. Thereafter, a conductive polymer such as polypyrrole can be deposited (e.g., electrodeposition) to form a conical composite structure 210a of increased dimension and mechanical strength. FIG. 2C shows SEM image of the conical composite structure 210a after deposition of the polypyrrole.

In yet another embodiment, a combination of scalloping and angled evaporation in which one side of the raised structure is metallized 220, results in growth starting at the base and along the metallized side. Thereafter, a conductive polymer such as polypyrrole can be deposited (e.g., electrodeposition) to form a bent conical composite structure 220a of increased dimension and mechanical strength. FIG. 2E shows SEM image of the bent conical composite structure 220a after deposition of the polypyrrole.

In certain embodiments, the composite structures can be utilized as the secondary structure by depositing primary structures (e.g., nanofibrils, nanoparticles, and the like) on the modified composite structures to form desired hierarchical structures.

In certain embodiments, any one or more of the primary, secondary, or higher order structures of the hierarchical structure can be coated with any desired material, such as silanization agents, fluorination agents, and other similar surfactants.

In certain embodiments, the choice of material may provide a desired wetting characteristic, ranging from improved wetting resistance to greater wettability of certain liquids, when compared to the particular wetting characteristics of non-hierarchical structures.

For example, providing a hydrophobic material or coating as part of the hierarchical structure may provide improved wetting resistance (e.g., superhydrophobicity) to polar liquids (e.g., water, alcohol, etc.) as compared to a non-hierarchical structure. Other materials or coating that can provide improved wetting resistance to polar liquids include fluorinated small molecules and hydrophobic polymers such as Teflon and polyethylene.

In contrast, providing a hydrophilic material or coating as part of the hierarchical structure may provide improved superhydrophilicity as compared to a non-hierarchical structure. Other materials or coating that can provide improved superhydrophilicity include porous substrates made of small molecules and polymers containing ionic groups or polar groups as well as some metal oxides rich with surface hydroxyl groups.

In certain embodiments, providing an oleophobic materials or coating as part of the hierarchical structure may provide improved superoleophobicity as compared to a non-hierarchical structure. Such materials include low surface energy coatings (e.g. fluorinated materials) with re-entrant curvatures that provide trapped air between the liquid and the solid substrate.

In certain embodiments, providing an oleophilic material or coating as part of the hierarchical structure may provide improved superoleophilicity as compared to a non-hierarchical structure. Such materials include porous substrates made of non-polar materials.

In certain embodiments, in addition to the improved wetting characteristics, the material choice may provide certain desired optical properties, such as reduced light reflection. For example, use of polypyrrole, due to its highly absorbing characteristic combined with its hierarchical structure, can provide an extremely dark (e.g., black) surface.

The choice of material is not limited. For example, hierarchical structures can be made with any combination of metals, semiconductors, polymers, small molecules, oligomers, ceramics, and the like. For example, materials such as nickel, copper, gold, aluminum, silicon, gallium arsenide, conducting polymers (e.g. polyaniline, polypyrrole, polythiophenes, etc.), non-conducting polymers (e.g., polystyrene, polyethylene, hydrogels, etc.), surfactants (e.g., silanization agents, fluorination agents, etc.), and numerous other types of materials can be utilized. Choice of particular material may alter the properties (e.g., fluorinated surfaces may resist wetting of water while attracting fluorinated liquids) as well as provide certain limits on the manufacturability of the hierarchical structures (e.g., electrodeposition may require a conducting material and conducting polymers may be utilized in such instances).

### Fabrication Methods

The “primary, secondary, tertiary, and higher-order structures” of the hierarchical structured surfaces of the present disclosure can be produced by numerous different techniques, such as photolithography, e-beam lithography, soft lithography, replica molding, solution deposition, solution polymerization, electropolymerization, electrospinning, electroplating, vapor deposition, contact printing, etching, transfer patterning, microimprinting, self-assembly, and the like. (See, e.g., Mark J. Madou “Fundamentals of microfabrication: the science of miniaturization” CRC Press 2002; John A. Rogers and Hong. H. Lee “Unconventional Nanopatterning Techniques and Applications” Wiley 2008; Guozhong Cao and Ying Wang “Nanostructures and Nanomaterials: Synthesis, Properties, and Applications” World Scientific Series in Nanoscience and Nanotechnology 2011; Geoffrey A Ozin, Andre C Arsenault, Ludovico Cademartiri, Chad A Mirkin “Nanochemistry: A Chemical Approach to Nanomaterials” Royal Society of Chemistry 2008, the contents of which are incorporated by reference herein.)

In certain embodiments, combination of different fabrication techniques can be employed to produce the hierarchical structures. For example, surface coatings with nanoscale “primary structures” formed on “secondary structures” having microscale feature sizes (e.g. arrays of high-aspect-ratio structures) can be generated as follows. First, the microscale secondary structures can be produced using lithographic and/or replication techniques, such as those described in U.S. Patent Publication No. 2011/0077172, entitled “Assembly and deposition of materials using a superhydrophobic surface structure” by Aizenberg and Hatton, and WO 09/158631, entitled “Versatile high aspect ratio actuatable nanostructured materials through replication” by Aizenberg and Pokroy, the contents of which are incorporated by reference herein in their entireties. Then, techniques such as spraying (see, e.g., A. Jaworek and A. T. Sobczyk “Electrospraying route to nanotechnology: An overview” Journal of Electrostatics, 2008, the contents of which is incorporated by reference herein), electrospinning (see, e.g., D. Li, Y. Xia “Electrospinning of Nanofibers: Reinventing the Wheel?” Advanced Materials, 2004, the contents of which is incorporated by reference herein), electrodeposition, and the like can be carried out to form nanoscale “primary structures” over the secondary structures.

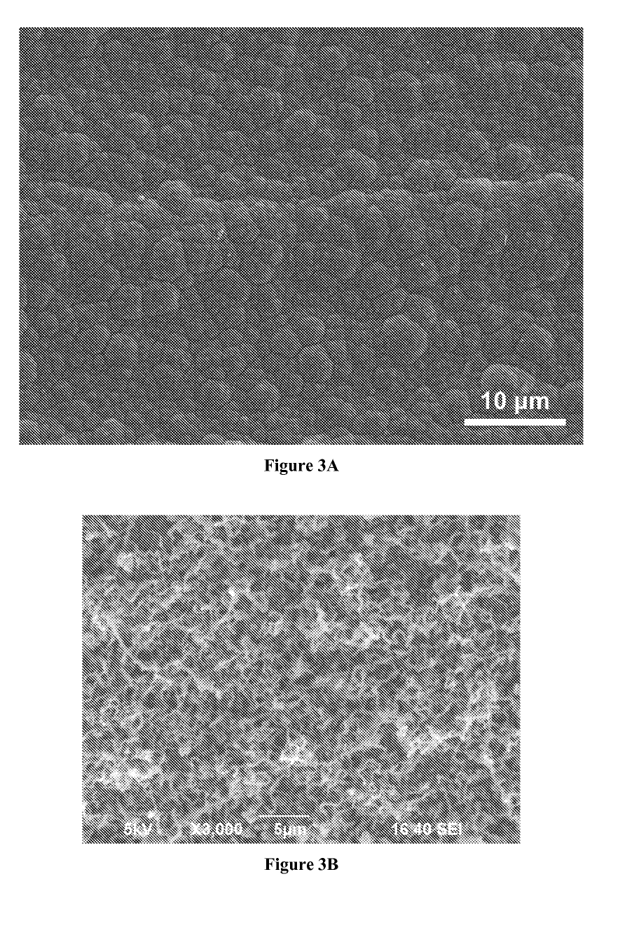

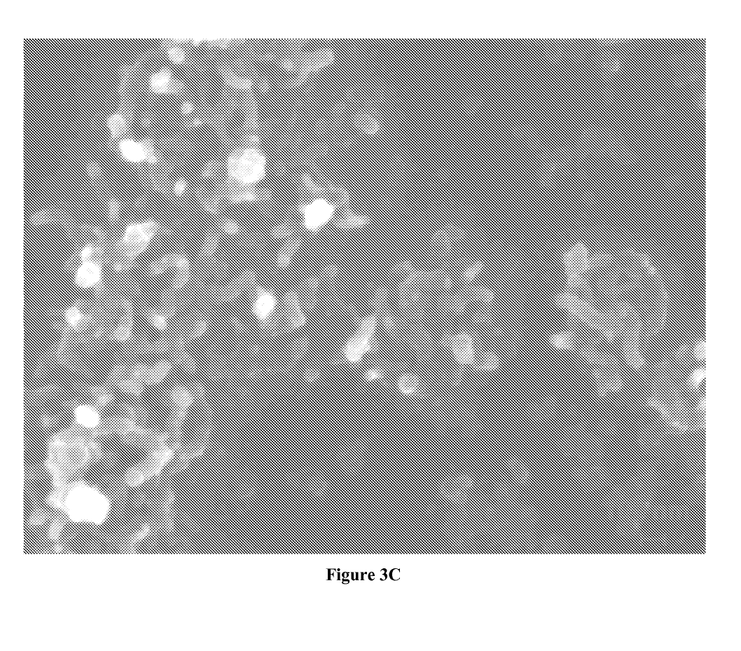

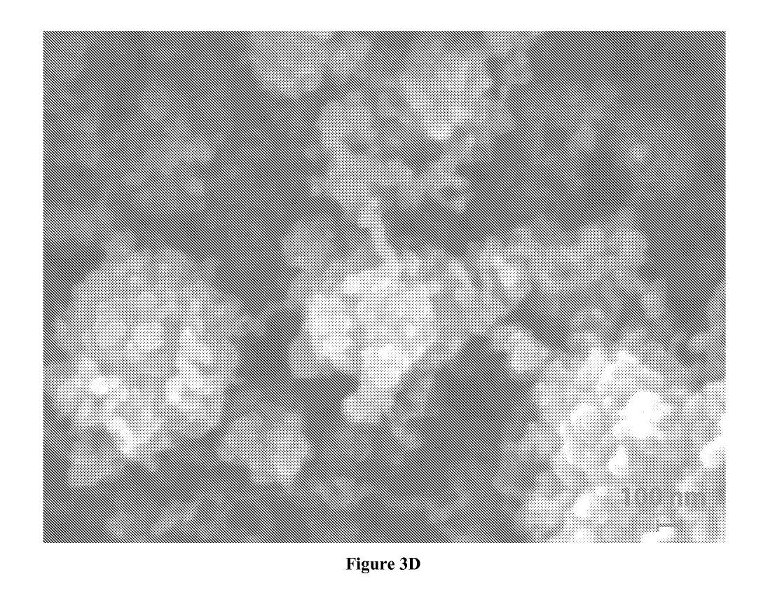

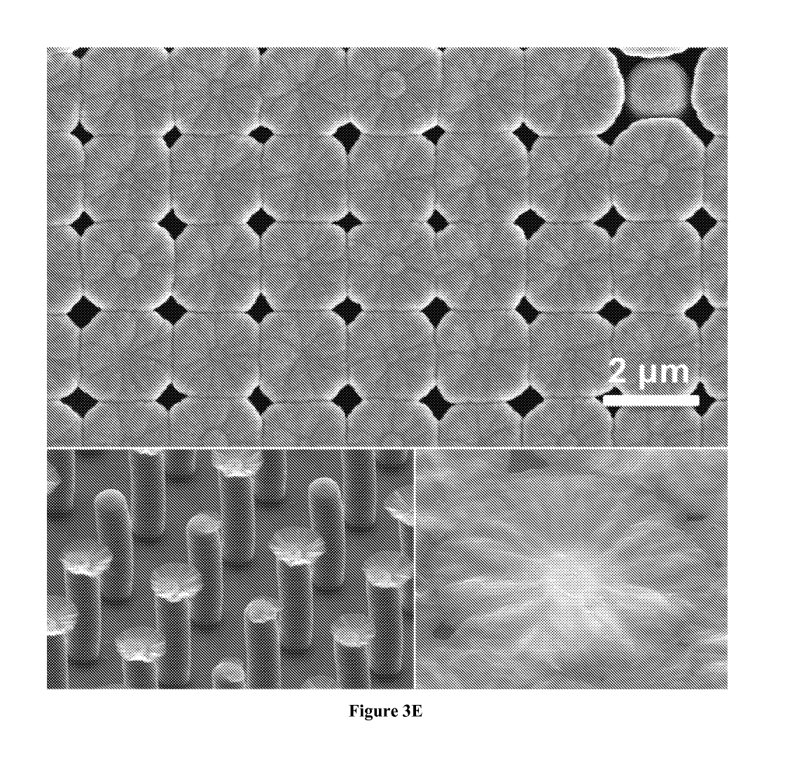

In situ deposition of conducting organic polymers by electrochemical deposition may be particularly useful technique in forming the hierarchical structures described herein. The morphology of the conducting organic polymers can be controlled by varying the deposition conditions such as the concentration of monomer, the types of electrolytes and buffers, the deposition temperature and time, and the electrochemical conditions such as applied potential. For example, increasing the concentration of monomer in the electrochemical solution, the applied potential, and/or the temperature generally leads to a faster polymerization rate and many parasitic nucleation sites during growth resulting in a morphology that is similar to a cauliflower (see FIG. 3A). In contrast, lower concentrations of monomer, lower applied potential, and lower temperatures can lead to nanofibrile growth with substantially uniform diameters (see FIG. 3B). Further decrease in concentration of monomer or applied potential can lead to short rods of polymer nanofibers with low surface coverage (see FIG. 3C). In another example, increasing the type of electrolytes and buffers to obtain a more acidic solution can lead to the formation of a cauliflower shape (see FIG. 3A) or overgrowth of polymers (see FIG. 3D). In another example, the applied voltage can be cycled leading to different oxidation states of the deposited polymer layer which is often manifested as a color change (e.g., from dark blue to a green then to a pale yellow color with increasing applied voltage). In yet another example, the applied voltage can be pulsed at a constant voltage to form polymers only on the tip of the underlying micropost structures, leading to a mushroom-like morphology (see FIG. 3E). Accordingly, the morphology of conducting organic polymers can be finely controlled from nanometers to over micrometer scales, and surface coatings with precisely controlled morphology can be produced by simple modifications, which promise the customization of various surface properties by design and control of the morphology.

In certain embodiments, the primary, secondary, tertiary, and/or any other higher-order structures can be fabricated simultaneously. For example, by controlling the processing parameters of electrodeposition (e.g., applied voltage, electrodeposition solution concentration, pH, time, and the like), structures that have more than one characteristic feature sizes can be produced. Exemplary structures that can be made include larger sized bumps with protrusion emanating from each bump.

In certain embodiments, the hierarchical structures can be formed on any arbitrarily shaped surfaces, such as refrigerator coils, large metal sheets, shingles, siding sheets, medical devices, inside of pipes (e.g., metallic or metallized water or oil pipes), tubings, hollow metallic structures, patterned electrodes, meshes, wires, porous conductive surfaces, and the like. For example, electrochemical deposition can be carried out on any surface that is conducting (e.g., gold, silver, platinum, steel, stainless steel, aluminum, copper, nickel, etc.). If the desired surface is not conducting, a thin layer of a conducting material can be deposited over the surface (e.g., vapor deposition, solution coating, electroless plating, etc.). Then, the desired hierarchical structures can be formed as described above thereon using, for example, electrochemical deposition. Such techniques can provide metallization of complex surfaces so that the hierarchical surfaces can be formed on even the most geometrically complex articles. Other suitable techniques that may be useful to form hierarchical structures on any arbitrarily shaped surfaces include electroless deposition, spray coating, spin coating, dip coating, vapor deposition, and the like. (See, e.g., Mark J. Madou “Fundamentals of microfabrication: the science of miniaturization” CRC Press 2002; John A. Rogers and Hong. H. Lee “Unconventional Nanopatterning Techniques and Applications” Wiley 2008, the contents of which is incorporated by reference).

In certain embodiments, the hierarchical structure can be chemically modified to further increase the wetting resistance to particular types of fluids. For example, the surface of the hierarchical structure (including primary, secondary, tertiary, and/or higher-order structures) can be chemically modified with a fluorinated groups to improve wetting resistance to polar liquids. In another example, the anionic dopant for the conductive polymer can be a fluorinated anion, for example, perfluorosebacic acid, to impart superhydrophobicity without post-deposition surface modification.

### Advantages

The present disclosure provides many significant advantages over conventional systems. For example, conventional methods for producing such high surface area, non-wetting surface coatings typically rely on extremely complex, expensive, multistep, serial, and low throughput nanofabrication methods. In contrast, the hierarchical structures in accordance with certain embodiments of the present disclosure can be produced by a low cost and simple one-step fabrication method over a large area with high fidelity.

Moreover, conventional surfaces produced by such undesirably costly and complicated fabrication techniques are extremely difficult to repair once damaged, due to the present limits in fabrication methods. In some other cases, although technically possible, repairing a damaged surface is practically not desirable due to high cost for repair. In contrast, many of the hierarchical structures in accordance with certain embodiments of the present disclosure, such as the nanofiber “primary structures” formed using electrodeposition over nanopost “secondary structures” described herein, can be easily regenerated after damage at low cost.

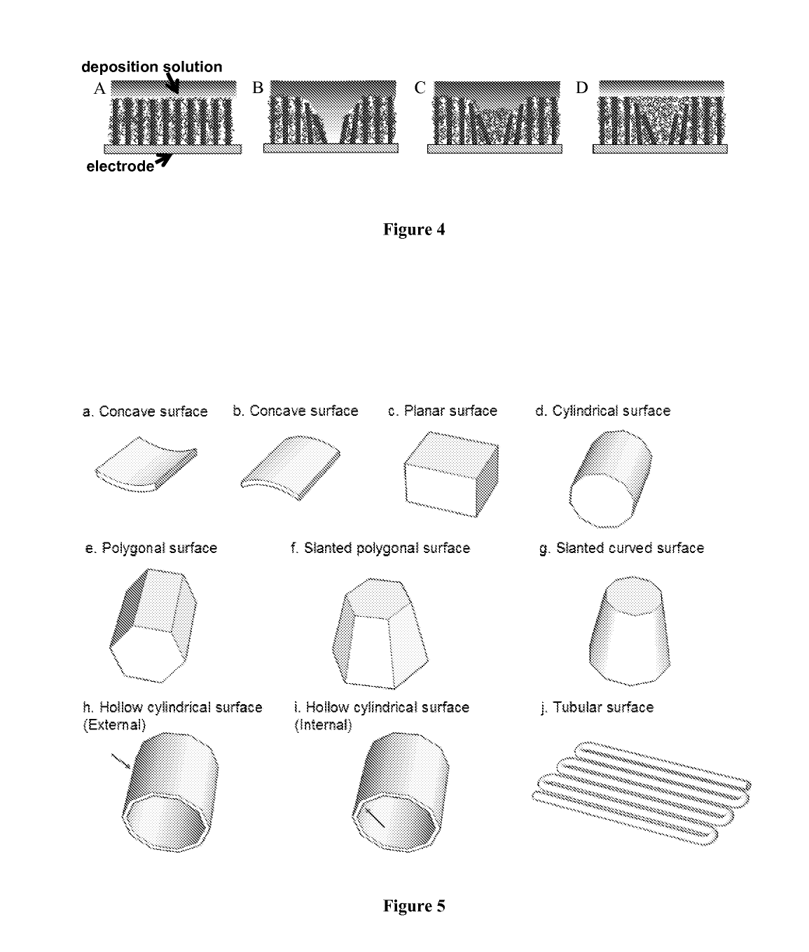

FIG. 4 schematically shows the proposed regeneration process. FIG. 4A shows a hierarchical structure without any damaged areas. In FIG. 4B, a locally damaged area (crack) can form during use, which can compromise, for example, the wetting resistance by exposing the surface of the electrode. To repair the damaged area, the damaged area can be exposed to an electrodeposition solution containing and subjected to conditions that allow growth of the polymer nanofibers. As shown in FIGS. 4C and 4D, the nanofibers can be locally grown only near the damaged region to the desired height. The repair process can be carried out as a localized process even though the entire substrate is exposed to the electrodeposition solution as the undamaged areas may resist wetting of the electrodeposition solution and prevent from the electrodeposition solution to reach the electrode and undergo nanofiber growth. Such facile repairability after damage adds a great versatility as well as energy and cost efficiency and allows the use of such hierarchical non-wetting structures where reinstallation, replacement, and external repair of the coating layers is practically impossible.

In certain embodiments, the hierarchical structures in accordance with certain embodiments can provide far superior wetting resistance as compared to untreated or even surfaces treated with just a primary structure. Without wishing to be bound by theory, the hierarchical structures may provide different size level of structures that prevent wetting at multiple size scales. In certain embodiments, the hierarchical structures may be able to maintain a Cassie state even at high impact pressures rather than transitioning to a Wenzel state as with conventional structures having only one size scale to promote wetting resistance. In certain embodiments, the hierarchical structures can be prepared using nanoposts that have greater mechanical stability (e.g., preparing nanoposts or other secondary structures that are wider, or even tapered such as being wider near the base than the top portion), which can in return further improve ability to withstand wetting at high impact pressures.

Moreover, the hierarchical structures in accordance with certain embodiments of the present disclosure can be produced on virtually any topographically patterned or flat surfaces. Some exemplary surfaces over which the hierarchical structures can be formed are illustrated in FIG. 5. Hence, the control of wetting with a wide range of liquids that would otherwise induce adverse effect on uncoated surfaces due to wetting and prolonged contact on a wide range of different surfaces can be achieved. For example, refrigerator coils which have highly contorted geometry can be provided with improved hierarchical wetting resistant surfaces.

### Applications

The present disclosure can be utilized in a number of applications where wetting of a surface is undesirable. Such applications include:
superhydrophobic coatings working at high pressure environment (e.g. sensor surface for well logging)
surface coatings for electrodes in supercapacitors, batteries, fuel cells (high surface area, high electron conductivity electrode)
anti-fogging coating (superhydrophilicity)—consumer optics
coatings for controlled condensation (turbines in power plant, collecting water in dry environment, military applications)
inner coating in pipelines for transporting oil with low resistivity
anti-bacterial coating
anti-icing coating, for example, outdoor signs, such as road signs, commercial graphics, billboards, and the like
superhydrophobic coating where repair is not practically possible (e.g. space applications, deep sea applications)
coatings for separation membranes (oil separation, filters, environmental applications)
cilia-like coatings providing propulsion mechanisms and flow control in microfluidics where electroactive polymers undergo reversible oxidation and reduction by applying voltage, which in turn leads to the migration of counter ions in and out of the polymer network to restore electroneutrality during the redox reaction. The counter ions are typically hydrated and can induce a large strain (up to 30%). By patterning electrodes and subsequently depositing conductive polymer around a cilia-like nanopost array, one can achieve controlled actuation of such nanostructures by applying voltage in an electrolyte solution.
adhesives under dry conditions (i.e., solid-solid interface) while maintaining anti-wetting properties (i.e., solid-liquid interface) when the surface chemistry is hydrophobic
anti-corrosive coating imparted by formation of conductive polymer coating around the underlying higher order structure

### EXAMPLES

### Example 1

A plurality of nanoposts were made by deep reactive ion etching of a Si wafer masked with an array pattern of circles of varying diameters, patterned by e-beam lithography or UV photolithography. The resulting nanoposts array formed on silicon was replicated by making a negative polydimethylsiloxane (DOW Sylgard 184 PDMS) mold. Then, a UV curable epoxy was cast in the negative PDMS mold. The replicated epoxy nanoposts served as parent structures where metal electrodes were patterned using either sputter-coating or shadow evaporation.

The subsequent electrochemical deposition of conductive organic polymers such as polypyrrole (PPy), polyaniline (PAni), and polythiophene (PTh) results in a new surface coating layer in which fine tuning of size and shape can be achieved.

Pyrrole (Py) was purified by an alumina column for small scale or by distillation prior to use. An aqueous solution of 0.1M pyrrole and 0.1 M sodium dodecylbenzene sulfonate (Na⁺DBS⁻) was prepared and purged by dry nitrogen for 10 minutes. To this solution, a template structure with patterned metal electrodes, as a working electrode, was placed. Then the polypyrrole films were electrochemically deposited using a standard three electrode configuration. An anodic potential of +0.55 V vs. Ag/AgCl (saturated with NaCl) was applied under a potentiostatic condition and a platinum mesh was used as a counter electrode. A gradient of the thickness of the deposited polypyrrole film was created by withdrawing the sample at a constant rate from the solution over a total deposition time. Freshly deposited polypyrrole layer was washed with deionized water and air blow dried.

For the continuous film deposition, an aqueous solution of 0.08-0.1 M pyrrole in 0.2-0.3 M PBS buffer (pH 6-7) and with 0.07 M lithium perchlorate (LiClO₄) was prepared and purged by dry nitrogen for 10 minutes. Typical three electrode configuration was used with a Pt wire and mesh counter electrode and a Ag/AgCl reference electrode. Linear scanning voltammetry starting from 0-0.5 V to 0.8-1.0 V at a rate of 1 mV/s was typically applied to the sample surface as working electrode for growth of thin PPy film followed by chronoamperometry at ˜0.85 V for additional time to grow fibrous PPy. Higher concentration of PBS (>0.25 M) and high pH (>7) tend to yield a uniform PPy nanofiber.

To deposit nanoballs, a higher concentration (>0.1 M) of pyrrole was used in 0.2-0.3 M PBS buffer (pH 6-7) and with 0.07 M lithium perchlorate (LiClO₄). Chronoamperometry at ˜0.85 V for 300-600 seconds resulted in the formation of nanoballs.

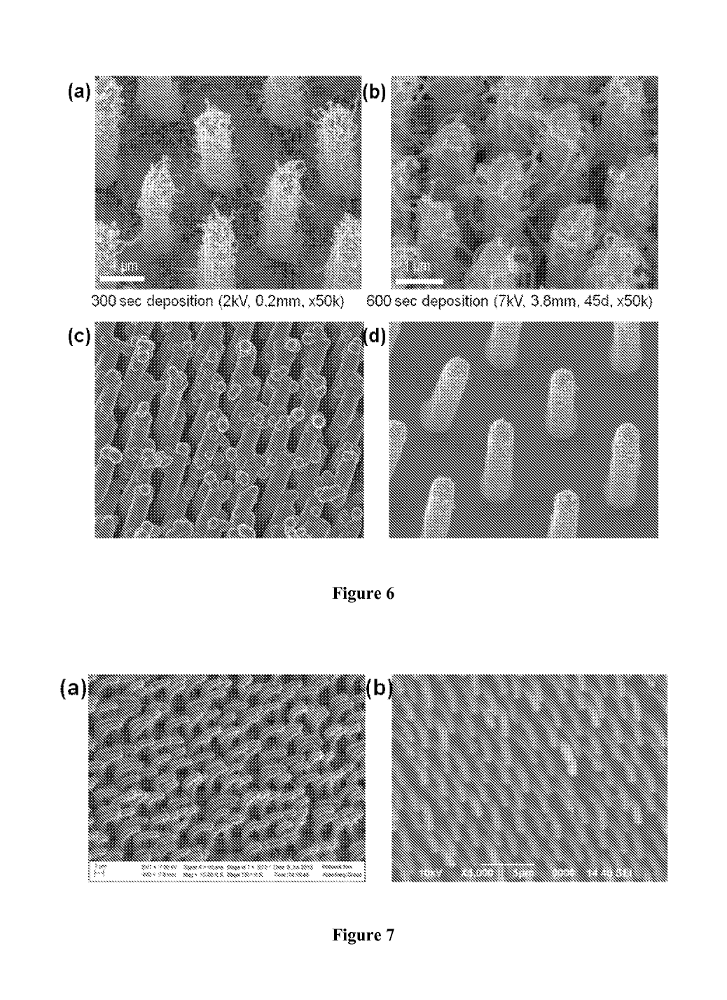

FIG. 6 shows complex hierarchical 3D nanostructured surface coatings generated using the sputter-coated nanoposts. As shown, hierarchical structures that resemble biological surfaces (e.g. plant leaves repelling water, insect skins repelling and selectively condensing water), that have nanofibers, or that have nanoballs are generated.

FIG. 7 shows hierarchical structures that have been formed using the nanoposts that were formed by line-of-sight depositions of metal electrodes (e.g. e-beam evaporation) to create on the structured surfaces. As shown in FIG. 7, superhydrophobic coating layer with anisotropy due to the bending of the structure caused by mismatched thermal expansion of the post and the deposited conducting polymer results. Such asymmetric structures closely resemble biological cilia, and show promise in applications where directional control of liquids is required, such as propulsion or flow control in microfluidic channels.

### Example 2

A plurality of epoxy nanoposts were prepared as described in Example 1.

Polyaniline (PANi) nanofibers were formed by utilizing a low concentration of aniline to form aligned nanofibers. Typically, 0.02 M aniline solution was prepared in a 1 M HClO₄ providing acidic condition, and an oxidizer, ammonium peroxysulfate (APS) was added at various ratios to aniline (aniline/APS=1 to 4). During the initial induction period, the substrates were placed over the solution by floating the substrate. The reaction was kept in a refrigerator (<4° C.) for 24 hr-48 hrs. The samples were then rinsed with deionized water and dried by either critical point drying or nitrogen blow drying. In some cases, the template surface was hydrophobically treated by exposing to a vapor of tridecafluoro-1,1,2,2-tetrahydrooctatrichlorosilane in a desiccator for 24 hrs.

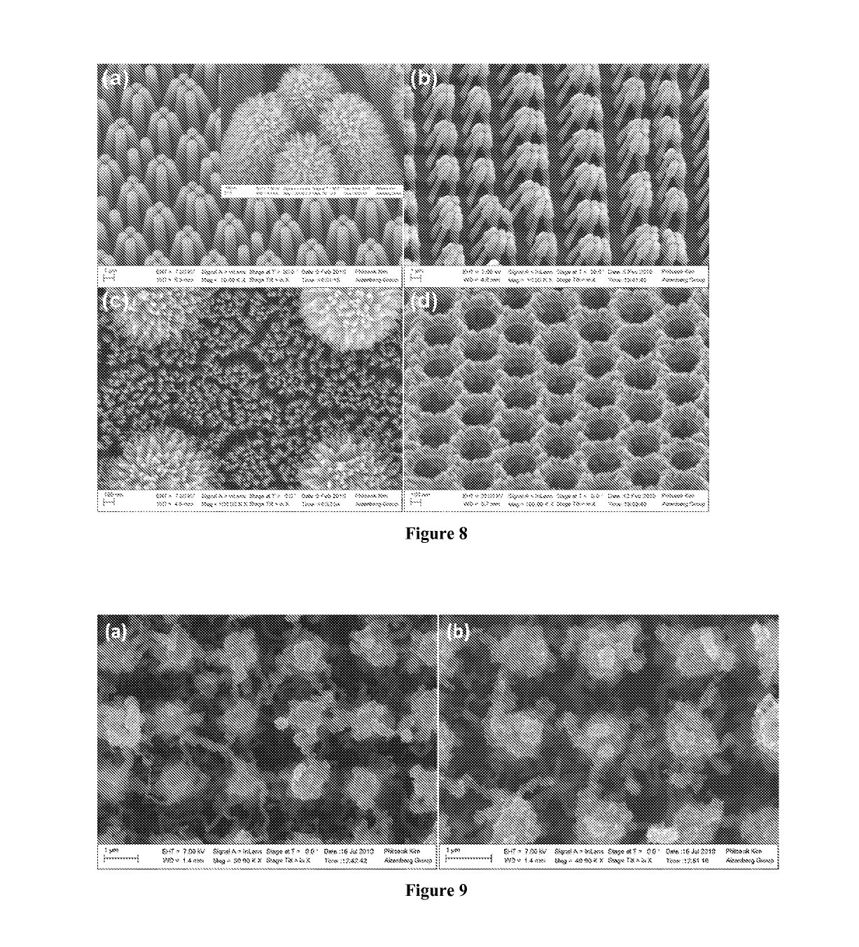

Direct solution deposition of polyaniline nanofibers onto high-aspect-ratio nanostructures resulted in a highly ordered hierarchical nanostructures. The electrodeposition and direct solution deposition can be combined to yield multi-hierarchical structures. For example, as shown in FIG. 8A (particularly the high resolution zoom image of the tip area in the inset of FIG. 8A), a densely packed, ordered 1D nanofibers can be electrodeposited on polymer nanoposts. Such structures may be beneficial for pressure-stable superhydrophobic surface, high surface area electrode, and anti-bacterial surface. FIG. 8B shows a selective deposition of polymer nanofibers only on the tip of the nanoposts. Such a surface can be utilized for controlled condensation of steam and water vapor as the condensation will be selectively focused on the tip area, and the coalesced water droplets can be easily removed and collected. FIG. 7C shows a setae-like surface, that can be potentially useful as dry adhesive due to an increase surface area of contact. FIG. 7D shows a porous inverse opal template covered with conductive polymer nanofibers, which can be potentially useful as a highly porous and high surface area electrodes for supercapacitors and batteries by providing a superhydrophilic and high surface area coating.

The coatings can be designed and produced by using two or more tiered roughness to further increase the stability of non-wetting state. For example, nanopost arrays can be first electrochemically treated to create coatings of 50-100 nm thick curly nanofiber network of PPy followed by an electroless deposition of 10-20 nm thick and ˜50 nm of short nanofibers of PANi. This may be able to further increase the surface roughness and result in even more reentrant curvatures in the coating layer.

Such a structure is shown in FIG. 9 showing SEM images of a hierarchical structure having primary, secondary and tertiary structures. The primary structure is 5-10 nm polyaniline nanofibers, the secondary structure is 50-150 nm polypyrrole nanofibers, and the tertiary structure is 300 nm nanopost array. In the image, the tertiary structure (300 m nanopost array) is not directly visible as the secondary structure (50-150 nm polypyrrole nanofibers) covers the tertiary structure. Moreover, the tertiary structure is not readily visible at the magnification, but show up as tiny white spots/fibrils emanating from the surfaces of the secondary structure.

### Example 3

Non-wetting properties of the hierarchical structures in accordance with certain embodiments of the present disclosure were examined by taking contact angle measurements of various liquids on the coating.

Several different surfaces were prepared, as noted below.
NG corresponds to epoxy replica of plain nanoposts (“nanograss”), each nanopost having a 300 nm diameter, 8 μm height, and a separation distance between the nanoposts of 2 μm, arranged in square array as one example of a “primary structure”
Flat+PPy corresponds to a flat epoxy substrate covered with PPy nanofiber having 50-100 nm diameter fibers randomly distributed on the surface as another example of a “primary structure”
Flat+PANi corresponds to a flat epoxy substrate covered with 10 nm diameter PANi nanofibers randomly distributed on the surface of the epoxy substrate as yet another example of a “primary structure”
NG+PPy corresponds to an epoxy replica of nanopost (“nanograss”) having 300 nm diameter posts, 8 μm heights, and a separation distance of 2 μm, arranged in square array, decorated with 50-100 nm diameter PPy nanofibers randomly distributed thereon as one example of a “primary structure” and “secondary structure”
NG+PANi corresponds to an epoxy replica of nanoposts (“nanograss”) each nanopost having a 300 nm diameter, 8 μm height, and a separation distance between the nanoposts of 2 μm, arranged in square array, decorated with 10 nm diameter PANi nanofibers randomly distributed thereon as a second example of a “primary structure” and “secondary structure”

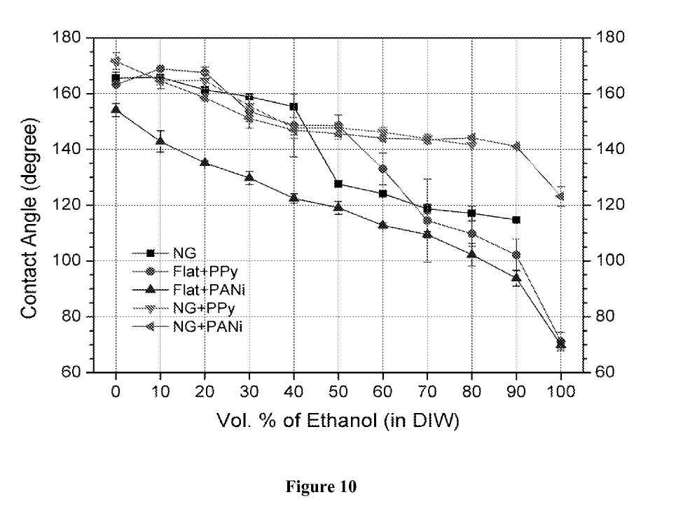

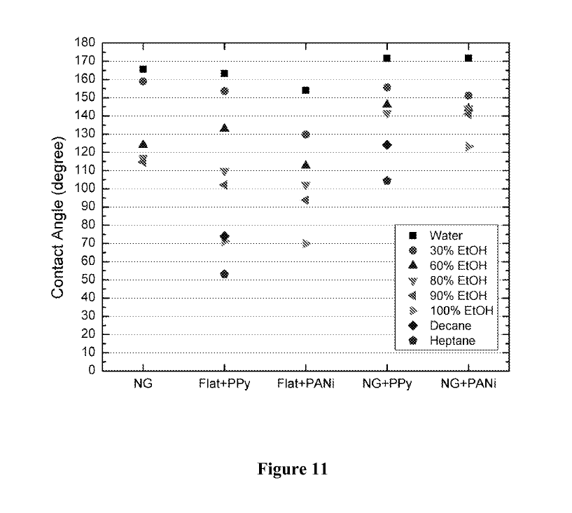

FIG. 10 shows the contact angle as a function of ethanol/deionized water ratio for the different structures described above. As shown, structures having hierarchical “primary” and “secondary” structures (labeled as NG+PPy and NG+PANi) are more resistant to wetting (as evidenced by higher contact angles) over a broader volume percentage of ethanol in water than the other structures having only a “primary structure.”

These results shown in FIG. 10 are reproduced in tabular form in Table 1. Generally, the measured contact angle is shown. In certain instances, if a droplet initially formed but during the course of contact angle measurement the liquid gradually sank and wet the substrate at room temperature, this behavior was classified as “kinetic wetting” (as opposed to “wetting” which immediately wet the surface). Without wishing to be bound by theory, it may be possible the kinetic wetting behavior arises due to the evaporation and re-condensation of ethanol. For hierarchical structures with high surface areas, kinetic wetting behavior was typically observed for liquids with high vapor pressure.

TABLE 1

| % EtOH | NG | Flat + PPy | Flat + PANi | NG + PPy | NG + PANi |
|---|---|---|---|---|---|
| 0 | 166 | 163 | 154 | 171 | 172 |
| 10 | 166 | 169 | 143 | 165 | 165 |
| 20 | 161 | 168 | 135 | 165 | 159 |
| 30 | 159 | 154 | 130 | 156 | 151 |
| 40 | 155 | 149 | 122 | 148 | 147 |
| 50 | 128 | 149 | 119 | 148 | 146 |
| 60 | 124 | 133 | 113 | 146 | 144 |
| 70 | 119 | 114 | 109 | 144 | 143 |
| 80 | 117 | 110 | 102 | 141 | 144 |
| 90 | 115 | 102 | 94 | kinetic | 141 |
| | | | | wetting | |
| 100 | wetting | 71 | 70 | kinetic | 123 |
| | | | | wetting | |

FIG. 11 shows the contact angle on the various different surfaces described for 100% water, 30% ethanol, 60% ethanol, 80% ethanol, 90% ethanol, 100% ethanol, decane, and heptane. The results shown in FIG. 11 are reproduced in tabular form below in Table 2.

TABLE 2

| | | 30% | 60% | 80% | 90% | 100% | | |
|---|---|---|---|---|---|---|---|---|
| Substrate | water | EtOH | EtOh | EtOH | EtOH | EtOH | Decane | Heptane |
| NG | 166 | 159 | 124 | 117 | 115 | wetting | wetting | wetting |
| Flat + PPy | 163 | 154 | 133 | 110 | 102 | 71 | 74 | 53 |
| Flat + PANi | 154 | 130 | 113 | 102 | 94 | 70 | Wetting | wetting |
| NG + PPy | 172 | 156 | 146 | 142 | kinetic | kinetic | 124 | 104 |
| | | | | | wetting | wetting | | |
| NG + PANi | 172 | 151 | 144 | 144 | 141 | 123 | N/A | N/A |

As shown, the hierarchical surfaces having both primary and secondary structures (NG+PPy and NG+PANi) generally has a higher contact angle for all solvents measured compared structures having only a primary structure (NG for 30% ethanol being the only anomaly).

### Example 4

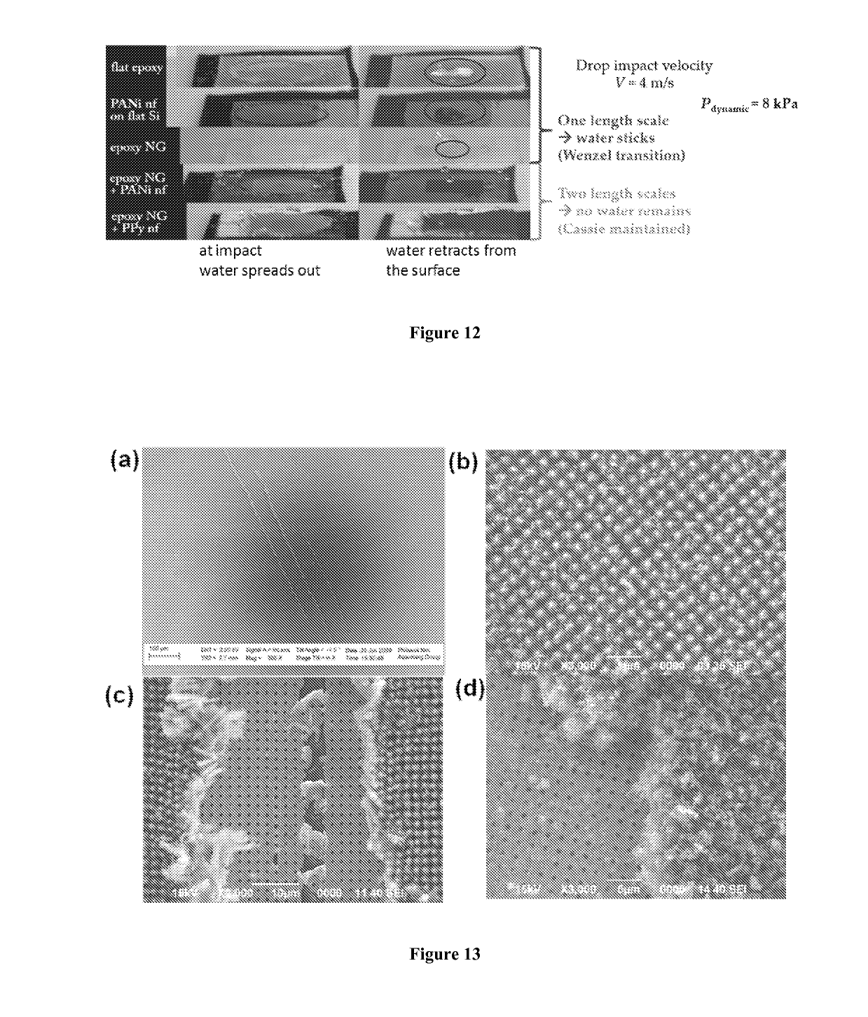

The hierarchically structured surfaces in accordance with certain embodiments of the present disclosure are able to withstand extremely high dynamic impact. Liquid droplets impacting the surfaces at velocities as high as the terminal velocity of a raindrop (9 m/s for 4 mm diameter rain drop) are repelled from these surfaces, while structures having only a “primary structure” undergo dynamic wetting. FIG. 12 are still shots from a movie taken by a high speed camera showing a water droplet impacting different types of surfaces. The following different surfaces were prepared:

Several different surfaces were prepared, as noted below.
Flat corresponds to a flat epoxy substrate
PANi nf on flat Si corresponds to a flat silicon substrate covered with 10 nm diameter PANi nanofibers randomly distributed on the surface of the silicon substrate as one example of a “primary structure”
Epoxy NG corresponds to epoxy replica of plain nanoposts (“nanograss”), each nanopost having a 300 nm diameter, 8 μm height, and a separation distance between the nanoposts of 2 μm, arranged in square array as one example of a “primary structure”
Epoxy NG+PANi nf corresponds to an epoxy replica of nanoposts (“nanograss”) each nanopost having a 300 nm diameter, 8 μm height, and a separation distance between the nanoposts of 2 μm, arranged in square array, decorated with 10 nm diameter PANi nanofibers randomly distributed thereon as a second example of a “primary structure” and “secondary structure”
Epoxy NG+PPy nf corresponds to an epoxy replica of nanopost (“nanograss”) having 300 nm diameter posts, 8 μm heights, and a separation distance of 2 μm, arranged in square array, decorated with 50-100 nm diameter PPy nanofibers randomly distributed thereon as one example of a “primary structure” and “secondary structure”

As shown in FIG. 12, at impact (P=8 kPa), water spreads out regardless of whether the surface has only “primary structures” (labeled as “PANi nf on flat Si” and “epoxy NG”) or a combination of “primary and secondary structures” (labeled as “epoxy NG+PANi nf” and “epoxy NG+PPy nf”). As the water retracts from the surface, the flat epoxy and the surfaces having only “primary structures” (labeled as “PANi nf on flat Si” and “epoxy NG”) all lose the desirable Cassie state, and transition into the Wenzel state, which causes the water to stick on the surface. In contrast, surfaces having a combination of “primary and secondary structures” (labeled as “epoxy NG+PANi nf” and “epoxy NG+PPy nf”) are able to maintain the Cassie state allowing improve repellency of water even at high impact.

### Example 5

Healing capability was examined by scratching the coating then exposing the coating in a solution containing conductive polymers. The undamaged area maintains the improved repellency and the solution containing the conductive organic polymers did not wet the surface undamaged areas. In contrast, the damaged area wet the solution, which allowed contact with the underlying electrode. Upon application of the necessary electrical current to grow the conductive nanofibers, the treated surfaces improved repellency.

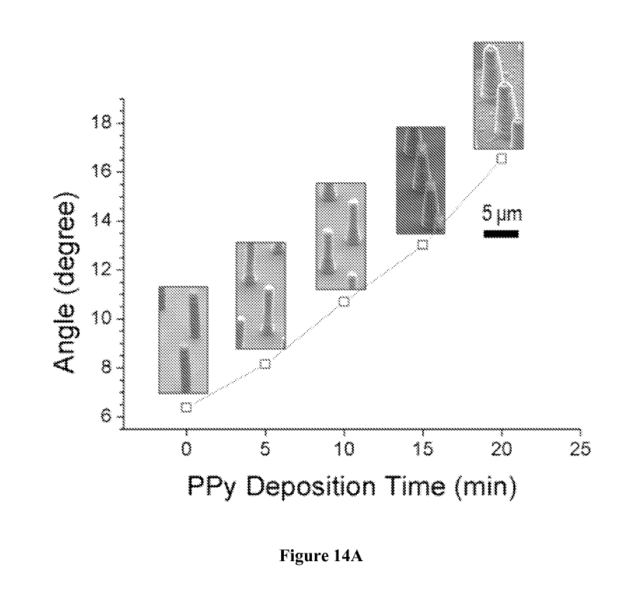

The deposition of new conductive organic polymers can be achieved by either electrochemical deposition (by applying voltage) or by direct solution deposition. As shown in FIG. 13A, a surface having a hierarchical structure of nanoposts and polymer nanofibers were damaged by scratching the surface. FIG. 13B shows an SEM image zoomed into an undamaged areas while FIG. 13C shows an SEM image zoomed into a damaged area. The entire surface was then exposed to a solution containing a conductive organic polymer and underwent conditions described above to grow the polymeric nanofibers. Deposition of nanofibers was not observed on undamaged portions, likely due to a non-wetting effect of the solution containing a conductive organic polymer. In contrast, as shown in FIG. 13D, the damaged area underwent localized wetting and partial repair by growing the nanofibers on only the damaged areas.

### Example 6

The secondary structure (or higher order structure) can be designed such that they exhibit improved mechanical strength against impact and scratch.

A commercial UV-curable epoxy resin (UVO114, Epotek) was cast in a PDMS mold bearing the negative of a parent structure to produce positive replicas. The original Si master was fabricated by the Bosch process and the HAR nanostructures therefore exhibited a characteristic wavy sidewall (“scalloping”) that was precisely reproduced in the epoxy replica. A 100-nm thick gold or platinum layer was then deposited on this epoxy parent structure by either sputter coating or electron beam evaporation. The metal layer served as the working electrode in an electrochemical cell having a typical three-electrode configuration; PPy was electrochemically deposited from an aqueous solution containing 0.1 M pyrrole (Py) and 0.1 M NaDBS under a potentiostatic condition (0.5 V-0.7 V vs. Ag/AgCl reference electrode). PPy deposition was also performed on a flat substrate to monitor the film thickness and the surface roughness. The rate of PPy deposition can be controlled by changing the voltage of electrodeposition, and can be maintained constant over at least a period of 20 min; precise control of voltage enables corresponding control of the size and shape of the resultant HAR structures

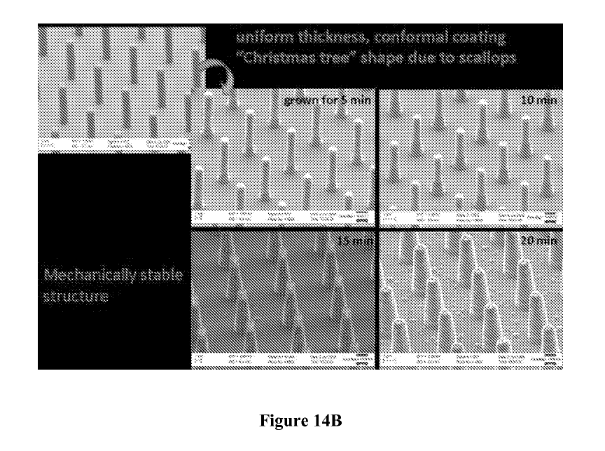

An example of reinforced secondary structure of post array are shown in FIGS. 14A and 14B. As shown in FIG. 14A, the diameter of the basal part of each micropost was increased by depositing PPy of varying thickness. Electrodeposition was performed in an aqueous solution containing 0.1 M NaDBS and 0.1 M pyrrole. The deposition voltage was about 0.65V. In this particular example, the metal electrodes were deposited by line-of-sight evaporation from an evaporation source aligned along the direction of each micropost. Due to the presence of scalloping (sidewall corrugation), the electrodes on the sidewall of each post form a series of isolated rings. As the electrodeposition of PPy takes place from the bottom surface, these isolated ring electrodes are electrically bridged by the freshly deposited, conductive PPy film. As a result, the basal part has thicker PPy layer than the top part and transforms a cylindrical post to a conical post reinforcing its mechanical properties. FIG. 14B compares the relative mechanical stability of the nanoposts having thicker basal regions as compared to the original nanoposts.

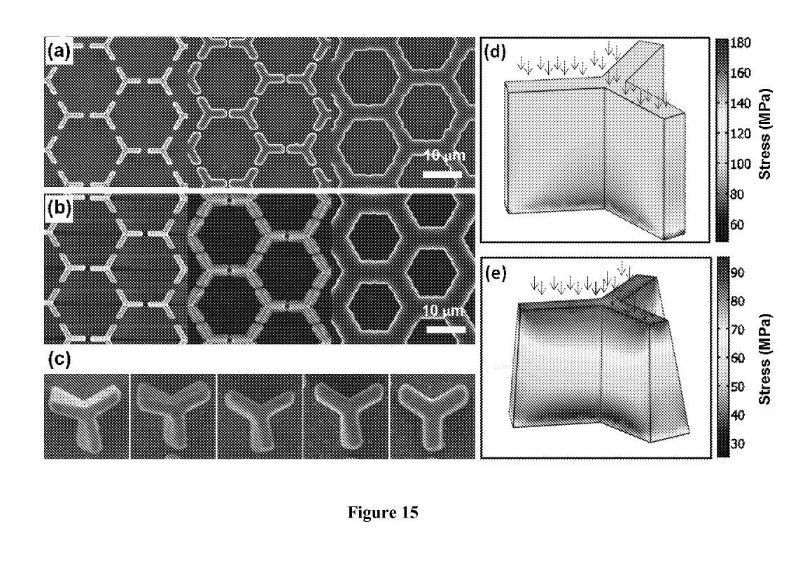

Another example of reinforced secondary structure is shown in FIGS. 15A to 15E. The arrays of Y-shaped microposts were strengthened by either uniformly increased thickness following conformal PPy deposition, (FIG. 15A), or by increased base thickness following STEPS II (FIG. 15A). In the latter case, the structures become tapered in cross-section and have increased width at the bottom to resist bending stresses. Agilent G200 nanoindentation system was utilized to compare the structural deformation of the original Y-micropost structure (FIG. 15C, left) and incrementally reinforced microstructures. 10 mN nanoindentations were applied with a standard Berkovich tip. FIG. 15C shows that permanent deformation sharply decreased as the structure was reinforced as less twisting of the Y-structure is evident on the right images (reinforced structures) while significant twisting of the Y-structure is evident on the left images. FIGS. 15D and 15E show finite element method (FEM) simulations to model the structural response of the epoxy replicas of the original Y-micropost (FIG. 15D) and a reinforced Y-micropost (FIG. 15E). A 5-μm-tall original Y-micropost structure with arm length of 4 μm and a width of 1 μm was modeled using COMSOL FEM software. The tapered Y-micropost structure was 2 μm wide at the bottom and tapered to a 1 μm at the top. A uniformly distributed compressive load of 100 MPa was assumed for both structures, using the material properties of UV-cured epoxy resin. The simulation results indicate that the tapered micropost structure exhibits a two-fold decrease in the maximum induced stresses compared to that of the original Y-micropost.

Moreover, the array of Y-shaped microposts demonstrate the range of characteristic features of the shape evolution that can be achieved to alter the secondary structures. Among other properties, it provides a good example of the transformation of isolated columns into a closed-cell structure with interconnected walls that can be utilized as new and different secondary structures.

### Example 7

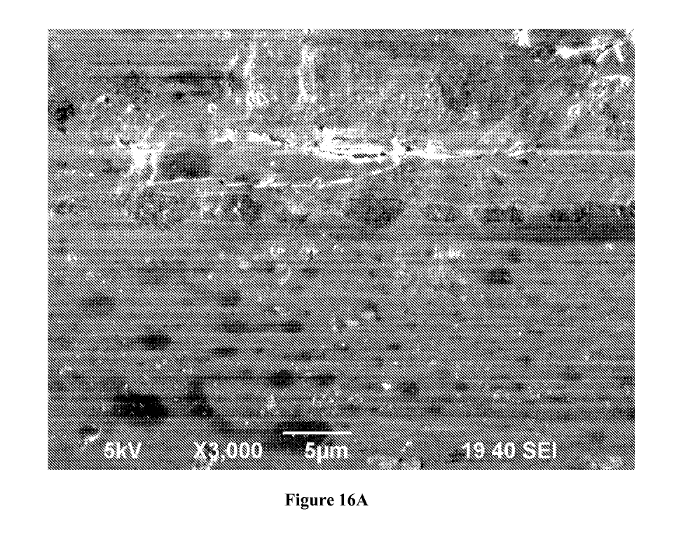

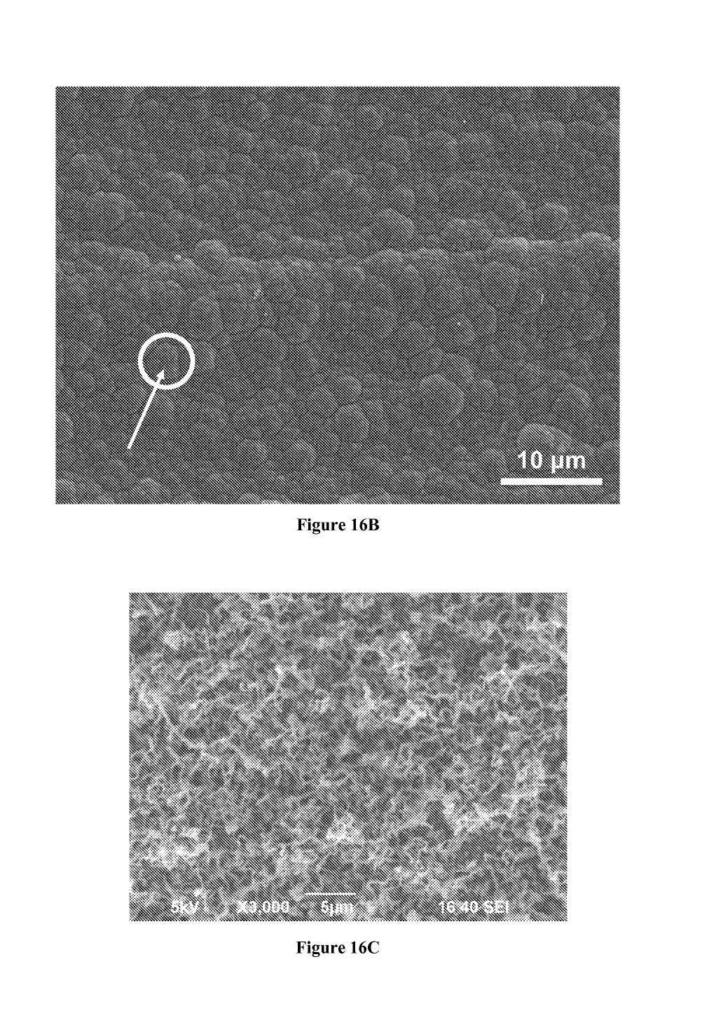

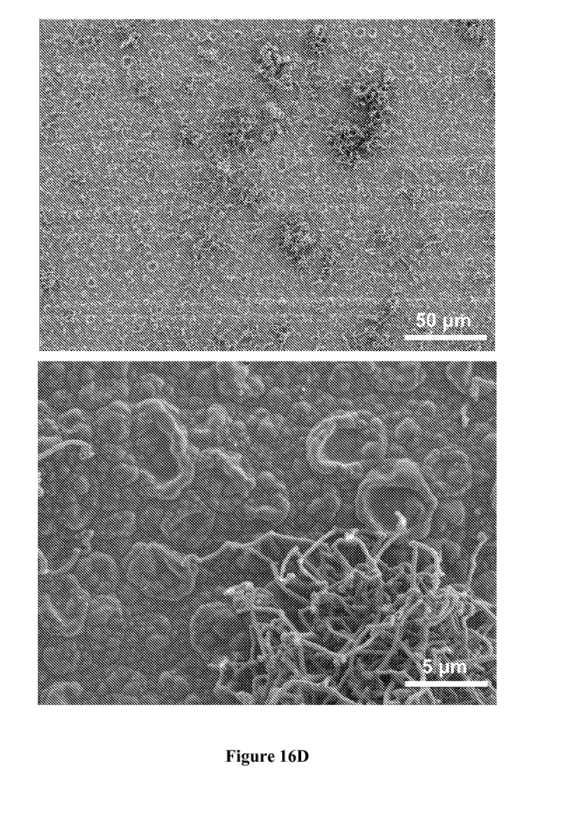

Al 1100 alloy was cut out from a refrigerator coil and flattened by using a hydraulic press, then cleaned in acetone for 15 minutes in an ultrasonic bath. FIG. 16A shows an SEM image of the Al 1100 alloy surface.

Electrochemical deposition of polypyrrole was carried out, under conditions that provide both a primary and secondary structure in a single layer, referred to in this example as a “first layer.” To deposit the first layer, an electrodeposition bath was prepared containing 0.1 M pyrrole, 0.1 M dodecylbenzenesulfonic acid, and sodium salt (SDBS) in deionized water. Pyrrole was purified by filtering through an alumina column and used immediately. The pH of the 0.1 M SDBS was made slightly acidic (pH ˜6.52) as it was realized that if the pH of SDBS is basic, the deposition becomes very slow and non-uniform on the Al 1100 alloy.

Standard three-electrode configuration was used for the electrodeposition using a potentiostat. A silver/silver chloride (saturated with NaCl) reference electrode was used. A large surface area platinum electrode (10 cm×10 cm, 100 mesh) was used as a counter electrode. It is important to have a high surface area counter electrode to achieve a uniform coating. It is also important to have the deposition bath constantly stirred for uniform deposition. Other types of counter electrodes (e.g. platinized titanium mesh) may be used as a counter electrode. A salt bridge may be also used if the counter and reference electrodes need to be separated from the main deposition bath.

The cleaned substrate was immersed in the deposition bath. After soaking the Al substrate for 10 minutes, the electrodeposition was performed by applying a constant potential of 0.9-1.0 V vs. Ag/AgCl for 0-600 seconds (i.e. chronoamperometry). After electrodeposition of the first layer, the substrate was rinsed with deionized water and dried by blowing air.

The counter electrode was placed vertically along the curvature of the container. When the substrate was placed vertically, the deposition takes place on the surface facing the counter electrode, then the backside. When the substrate was placed horizontally, the deposition takes place on the bottom surface, then the top surface.

FIG. 16B shows an SEM image of the first layer. As shown, the deposited first layer includes a plurality of bumps (secondary structure), along with a plurality of fine scale protrusions on each of the bump surfaces (primary structure). One exemplary bump is outlined by the white circle and one exemplary protrusion is indicated by the white arrow in FIG. 16B. Accordingly, both the primary and secondary structures were deposited simultaneous by selecting the appropriate electrodeposition conditions.

A second electrochemical deposition was carried out. The second electrodeposition bath contained 0.2 M phosphate buffer (pH=6-7), 0.01-0.1 M perchlorate (e.g. LiClO4) solution and 0.08-0.1 M pyrrole in deionized water. Nitrogen was bubbled through the solution prior to use. In some instances, additional templating agents may be added (e.g. soluble starch, heparin, polystyrenesulfone, etc.).

It should noted that deposition directly on Al 1100 surface using the second electrodeposition bath did not work as the aluminum at the anode (working electrode) was oxidized before the pyrrole monomer was able to oxidize and polymerize. The oxidized aluminum (aluminum ion) tends to react with the phosphate anion which leads to white precipitating salts on the surface of the Al electrode. However, carrying out the electrodeposition using the same conditions for Al 1100 having the first layer described above, a second layer of polypyrrole was successfully deposited, to form nanofibrils over the first layer. FIG. 16C shows an SEM image of the structure polypyrrole nanofibrils formed over the first layer.

If the concentration of pyrrole monomer is increased to 0.12 M in the second bath, toroid shaped morphology is formed, along with a lower density of nanofibers. Moreover, as shown in FIG. 16D, the plurality of fine scale protrusions are also present. Accordingly, the technique illustrates that primary, secondary, and tertiary structures can all be formed in a single process.

### Example 8

All samples from Example 7 were fluorinated by placing the samples in a vacuum desiccator with a few drops of heptadecafluoro-1,1,2,2-tetrahydrooctyl trichlorosilane placed in a small vial for more than 24 hours.

After fluorosilanization, the hydrophobicity the samples was tested by measuring static contact angle of deionized water on each sample using a contact angle goniometer as shown below in Table 3.

TABLE 3

| Sample | Bare Aluminum | After 1^{st} bath | After 2^{nd} bath |
|---|---|---|---|
| Contact angle | ~110° | ~130° | >150° |

Ice/frost formation test was performed in a homemade humidity and temperature-controlled chamber. On a thermoelectric cooler with a 45 degree tilt angle, the samples were mounted by using a thermal conductive paste. The humidity was actively controlled to maintain RH=60%. After reaching a steady humidity, the temperature of the samples was set to 5 degree C. From this point, a movie file was recorded while cooling the samples to −20 degree C. at 2 degree C./min.

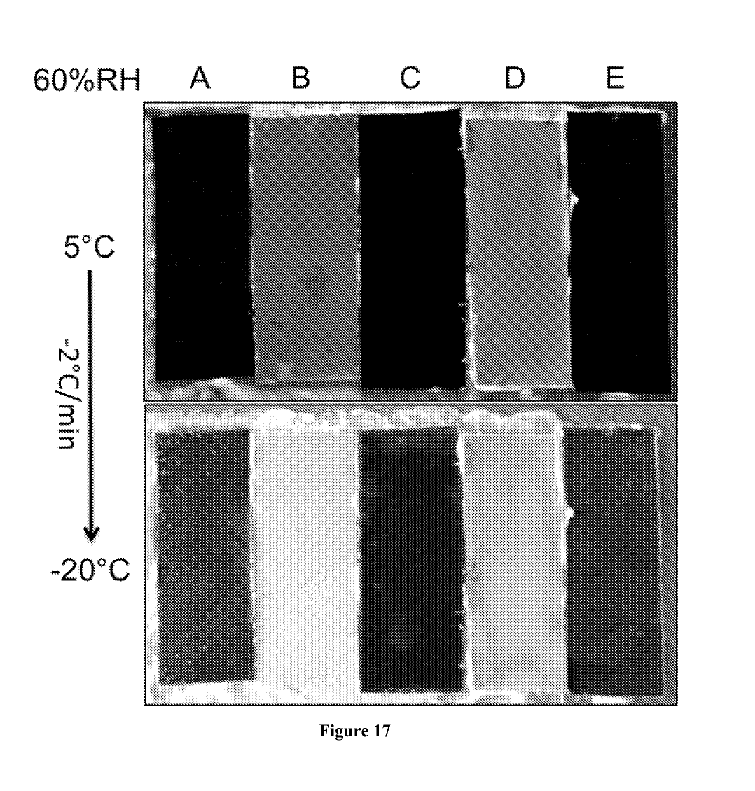

FIG. 17 shows a series of still frame captures from the recorded movie for the following different samples. Sample A corresponds to Al 1100 alloy coated with polypyrrole having a cauliflower-like morphology (bumps and protrusions extending from the bumps) along with nanofibrils of polypyrrole (see FIG. 16C). Sample B corresponds to bare Al 1100 alloy coated with fluorosilane. Sample C corresponds to Al 1100 alloy coated with polypyrrole having a cauliflower-like morphology (bumps and protrusions extending from the bumps) (see FIG. 16B). Sample D corresponds to bare Al 1100 alloy. Lastly, Sample E corresponds to Al 1100 alloy coated with polypyrrole having a cauliflower-like morphology (bumps and protrusions extending from the bumps) and as well as the toroid shape materials thereon (see FIG. 16D). As shown, hierarchically structured surface coatings (samples A, C and E) significantly resist frost formation compared to uncoated Al substrates. More specifically, frost formation is significantly delayed on the samples with PPy coatings, and the frost accumulation is reduced (with most notable reduction observed on the cauliflower-coated sample). Note also that frost formation on PPy-coated samples mostly occurs at the edges of the sample where it deposits on the neighboring material and proceeds to coat the tested area).

Upon review of the description and embodiments of the present invention, those skilled in the art will understand that modifications and equivalent substitutions may be performed in carrying out the invention without departing from the essence of the invention. Thus, the invention is not meant to be limiting by the embodiments described explicitly above.

1. An article comprising:
a substrate comprising a primary structure and a secondary structure, wherein the secondary structure is disposed on the substrate and the primary structure is disposed on at least a portion of the secondary structure,
the primary structure having at least one primary characteristic feature having a dimension on the nanoscale;
the secondary structure having at least one secondary characteristic feature having a dimension larger than the dimension of the primary characteristic features, wherein
the primary structure and the secondary structure provide improved control of wetting characteristics over that of the primary structure or the secondary structure alone.

2. The article of claim 1, wherein the primary structure comprises a plurality of bumps and the secondary structure comprises a plurality of protrusions extending form the surface of the bumps.

3. An article comprising:
a substrate comprising a primary structure, a secondary structure and a tertiary structure, wherein the tertiary structure is disposed on the substrate, the secondary structure is disposed on at least a portion of the tertiary structure, and the primary structure is disposed on at least a portion of the secondary structure,
the primary structure having at least one primary characteristic feature having a dimension on the nanoscale;
the secondary structure having at least one secondary characteristic feature having a dimension larger than the dimension of the primary characteristic features,
the tertiary structure having at least one tertiary characteristic feature having a dimension larger than the dimension of the secondary characteristic features, wherein
the primary structure, the secondary structure, and the tertiary structure provide improved control of wetting characteristics over that of the primary structure, the secondary structure, or the tertiary structure alone.

4. The article of claim 1, wherein the primary structure is disposed on at least a portion of the substrate.

5. The article of claim 1, wherein the size of the at least one primary characteristic features are tens of nanometers.

6. The article of claim 1, wherein the primary structure comprises a plurality of nanofibers, rods, nanoparticles, nanoballs, protrusions, or combinations thereof.

7. The article of claim 1, wherein the secondary structures or tertiary structures include a plurality of posts, honeycombs, bricks, bumps and combinations thereof.

8. The article of claim 1, wherein the secondary structures or the tertiary structures include a plurality of raised structures wherein the base of the raised structures have a larger dimension than the top of the raised structures.

9. The article of claim 1, wherein the article controls wetting of liquid is water, alcohol, oil, or mixtures thereof.

10. The article of claim 1, wherein at least one of the primary structure or the secondary structure is repairable after damage.

11. The article of claim 1, wherein the substrate is substantially nonplanar.

12. The article of claim 1, wherein the primary structure comprises a conducting polymer.

13. The article of claim 1, wherein the hierarchical structure forms a cilia-like structure that actuates upon application of voltage in an electrolyte solution.

14. The article of claim 1, wherein the hierarchical structure forms a coating for displays, electrodes, optical materials, turbines, anti-bacterial surfaces, or separation membranes.

15. A method comprising:
providing a substrate;
providing a primary structure having at least one primary characteristic features having a dimension on the nanoscale;
providing a secondary structure having at least one secondary characteristic features having a dimension larger than the dimension of the primary characteristic features;
wherein the secondary structure is disposed on the substrate and the primary structure is disposed on at least a portion of the secondary structure; and
wherein the primary structure and the secondary structure provide improved control of the wetting characteristics over that of the primary structure or the secondary structure alone.

16. The method of claim 15, wherein the primary structure comprises a plurality of bumps and the secondary structure comprises a plurality of protrusions extending form the surface of the bumps.

17. A method comprising:
providing a substrate;
providing a primary structure having at least one primary characteristic features having a dimension on the nanoscale;
providing a secondary structure having at least one secondary characteristic features having a dimension larger than the dimension of the primary characteristic features;
providing a tertiary structure having at least one tertiary characteristic features having a dimension larger than the dimension of the secondary characteristic features;
wherein the tertiary structure is disposed on the substrate, the secondary structure is disposed on at least a portion of the tertiary structure, and the primary structure is disposed on at least a portion of the secondary structure; and
wherein the primary structure, the secondary structure, and the tertiary structure provide improved control of wetting characteristics over that of the primary structure, the secondary structure, or the tertiary structure alone.

18. The method of claim 15, wherein the primary structure is disposed on at least a portion of the substrate.

19. The method of claim 15, wherein the size of the at least one primary characteristic features are tens of nanometers.

20. The method of claim 15, wherein the primary structure comprises a plurality of nanofibers, rods, nanoparticles, nanoballs, protrusions, or combinations thereof.

21. (canceled)

22. The method of claim 15, further comprising repairing at least one of the primary structure or the secondary structure after damage.

23. The method of claim 15, further comprising forming said primary structure and secondary structure simultaneously.

24. The method of claim 15, further comprising modifying the secondary structure or the tertiary structure to provide improved mechanical stability.

25. The method of claim 24, wherein the secondary structures or the tertiary structures include a plurality of raise structures wherein the base of the raised structures have a larger dimension than the top of the raised structures.

26. A method of repelling a substance, the method comprising;
providing the article of claim 1, and
exposing the article to the substance.

27. The method of claim 26, wherein the substance is a liquid.

28. The method of claim 26, wherein the liquid is aqueous.

29. The method of claim 26, wherein the liquid is organic.

30. The method of claim 26, wherein the substance is a solid.

31. The method of claim 26, wherein the solid is ice, frost or snow.
